(19) United States
(12) Patent Application Publication
(10) Pub. No.: US 2025/0017018 A1
(43) Pub. Date: Jan. 9, 2025

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Seongjae GO, Suwon-si (KR); Duyoung YANG, Suwon-si (KR); Kangmin KIM, Suwon-si (KR); Jongseon AHN, Suwon-si (KR); Byeongin CHOE, Suwon-si (KR)

(21) Appl. No.: 18/640,811

(22) Filed: Apr. 19, 2024

(30) Foreign Application Priority Data
Jul. 5, 2023 (KR) 10-2023-0087296

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A semiconductor device includes a plate layer; gate electrodes stacked and spaced apart from each other on the plate layer and including first gate electrodes and a second gate electrode on the first gate electrodes; first channel structures extending in the first gate electrodes; and second channel structures extending in the second gate electrode and electrically connected to the first channel structures, respectively, wherein the second gate electrode includes a metal material, and wherein each of the second channel structures includes a second channel layer, a second gate dielectric layer between the second channel layer and the second gate electrode, a second channel buried insulating layer on an internal side surface of the second channel layer, a second channel pad on the second channel buried insulating layer, and a second pad oxide layer on the second channel pad and the second channel layer.

### CROSS-REFERENCE TO RELATED APPLICATION(S)

This application claims benefit of priority to Korean Patent Application No. 10-2023-0087296 filed on Jul. 5, 2023 in the Korean Intellectual Property Office, the disclosure of which is incorporated herein by reference in its entirety.

### BACKGROUND

Example embodiments of the present disclosures relate to semiconductor devices and data storage systems including the same.

Semiconductor devices able to store high-capacity data in data storage systems requiring data storage have been necessary. Accordingly, methods for increasing data storage capacity of semiconductor devices have been researched. For example, as methods for increasing data storage capacity of semiconductor devices, semiconductor devices including memory cells disposed three-dimensionally, instead of memory cells disposed two-dimensionally, have been suggested.

### SUMMARY

Example embodiments of the present disclosures are to provide semiconductor devices having improved electrical properties and reliability.

Example embodiments of the present disclosures are to provide data storage systems including semiconductor devices having improved electrical properties and reliability.

According to an example embodiment of the present disclosure, a semiconductor device includes a first semiconductor structure that includes a substrate, circuit devices on the substrate, and circuit interconnection lines on the circuit devices; and a second semiconductor structure on the first semiconductor structure, wherein the second semiconductor structure includes: a plate layer; gate electrodes that include a lower select gate electrode, memory gate electrodes, and an upper select gate electrode sequentially stacked on the plate layer, wherein the gate electrodes are spaced apart from each other in a first direction that is perpendicular to an upper surface of the plate layer; first isolation regions that extend in the lower select gate electrode and the memory gate electrodes in a second direction that is perpendicular to the first direction; second isolation regions that extend in the upper select gate electrode in the second direction; a horizontal insulating layer between the memory gate electrodes and the upper select gate electrode; first channel structures that extend in the lower select gate electrode and the memory gate electrodes in the first direction; second channel structures that extend in the upper select gate electrode and the horizontal insulating layer and are electrically connected to the first channel structures, respectively; and a gate barrier layer on a side surface and a lower surface of the upper select gate electrode, wherein the upper select gate electrode includes a metal material.

According to an example embodiment of the present disclosure, a semiconductor device includes a plate layer; gate electrodes that are stacked and spaced apart from each other on the plate layer in a first direction that is perpendicular to an upper surface of the plate layer, wherein the gate electrodes include first gate electrodes and a second gate electrode on the first gate electrodes; first channel structures that extend in the first gate electrodes in the first direction; and second channel structures that extend in the second gate electrode in the first direction, wherein the second channel structures are electrically connected to the first channel structures, respectively, wherein the second gate electrode includes a metal material, and wherein each of the second channel structures includes a second channel layer, a second gate dielectric layer between the second channel layer and the second gate electrode, a second channel buried insulating layer on an internal side surface of the second channel layer, a second channel pad on the second channel buried insulating layer, and a second pad oxide layer on the second channel pad and the second channel layer.

According to an example embodiment of the present disclosure, a data storage system includes a semiconductor storage device that includes a first semiconductor structure, a second semiconductor structure on the first semiconductor structure, and an input/output pad, wherein the first semiconductor structure includes circuit devices, and the input/output pad is electrically connected to the circuit devices; and a controller that is electrically connected to the semiconductor storage device through the input/output pad and configured to control the semiconductor storage device, wherein the second semiconductor structure includes: a plate layer; gate electrodes that are stacked and spaced apart from each other on the plate layer in a first direction that is perpendicular to an upper surface of the plate layer, wherein the gate electrodes include first gate electrodes and a second gate electrode on the first gate electrodes; first channel structures that extend in the first gate electrodes in the first direction; and second channel structures that extend in the second gate electrode in the first direction, wherein the second channel structures are electrically connected to the first channel structures, respectively, wherein the second gate electrode includes a metal material, and wherein each of the second channel structures includes a second channel layer, a second gate dielectric layer between the second channel layer and the second gate electrode, a second channel pad on an internal side surface of the second channel layer, and a second pad oxide layer on the second channel pad and the second channel layer.

### BRIEF DESCRIPTION OF DRAWINGS

The above and other aspects, features, and advantages of the present disclosures will be more clearly understood from the following detailed description, taken in combination with the accompanying drawings, in which:

FIG. 1 is a plan view illustrating a semiconductor device according to an example embodiment of the present disclosure;

FIG. 2 is a cross-sectional view illustrating a semiconductor device according to an example embodiment of the present disclosure;

FIGS. 3A and 3B are enlarged views illustrating portions of a semiconductor device according to an example embodiment of the present disclosure;

FIG. 4 is a plan view illustrating a semiconductor device according to an example embodiment of the present disclosure;

FIGS. 5A and 5B are enlarged views illustrating a portion of a semiconductor device according to an example embodiment of the present disclosure;

FIG. 6 is a cross-sectional view illustrating a semiconductor device according to an example embodiment of the present disclosure;

FIG. 7 is a cross-sectional view illustrating a semiconductor device according to an example embodiment of the present disclosure;

FIGS. 8A to 8S are cross-sectional views illustrating a method of manufacturing a semiconductor device according to an example embodiment of the present disclosure;

FIG. 9 is a view illustrating a data storage system including a semiconductor device according to an example embodiment of the present disclosure;

FIG. 10 is a perspective view illustrating a data storage system including a semiconductor device according to an example embodiment of the present disclosure; and

FIG. 11 is a cross-sectional view illustrating a semiconductor package according to an example embodiment of the present disclosure.

### DETAILED DESCRIPTION

Hereinafter, embodiments of the present disclosure will be described as follows with reference to the accompanying drawings.

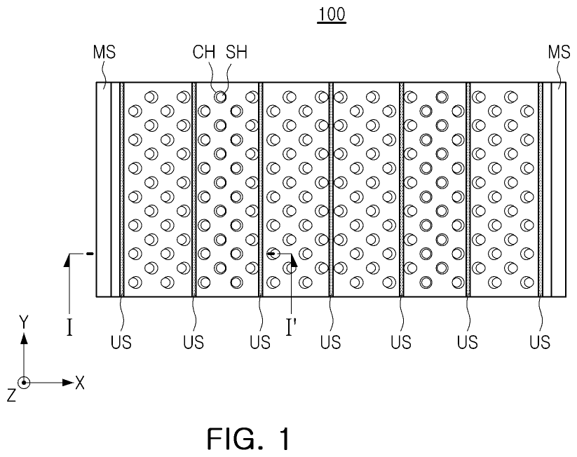

FIG. 1 is a plan view illustrating a semiconductor device according to an example embodiment.

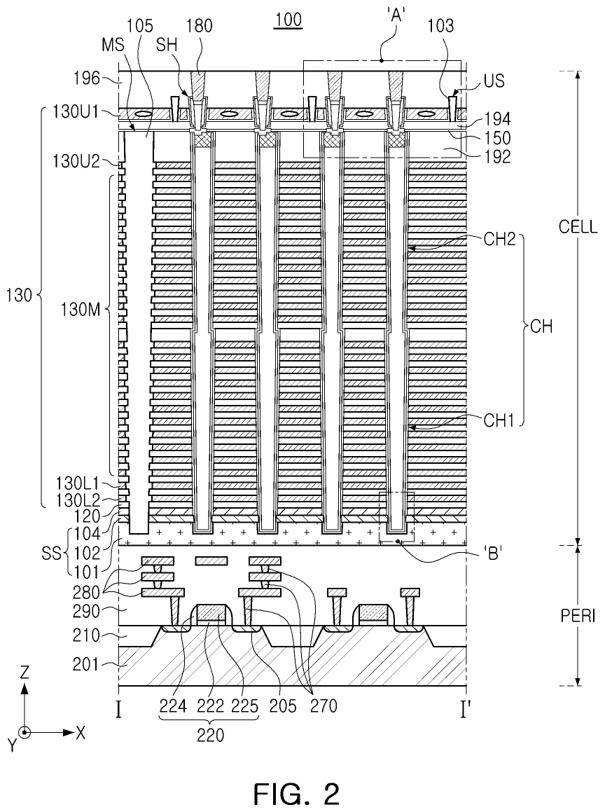

FIG. 2 is a cross-sectional view illustrating a semiconductor device according to an example embodiment, taken along line I-I′ in FIG. 1.

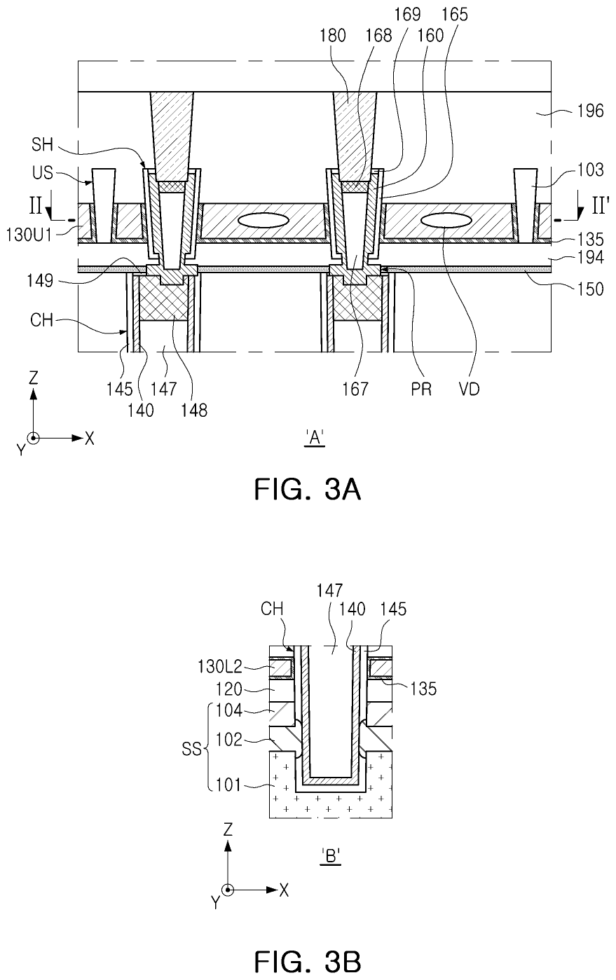

FIGS. 3A and 3B are enlarged views illustrating portions of a semiconductor device according to an example embodiment. FIG. 3A is an enlarged view illustrating region ‘A’ in FIG. 2. FIG. 3B is an enlarged view illustrating region ‘B’ in FIG. 2.

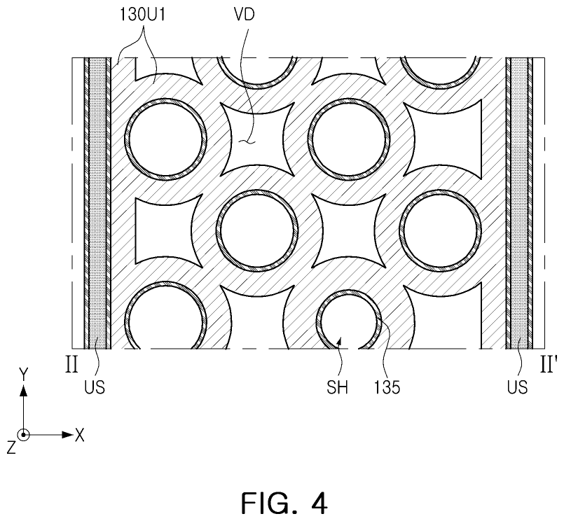

FIG. 4 is a plan view illustrating a semiconductor device according to an example embodiment, taken along line II-II′ in FIG. 3A.

Referring to FIGS. 1 to 4, a semiconductor device 100 may include a peripheral circuit region PERI, which is a first semiconductor structure including a substrate 201, and a memory cell region CELL, which is a second semiconductor structure including a plate layer 101. The memory cell region CELL may be disposed on the peripheral circuit region PERI. In example embodiments, conversely, the memory cell region CELL may be disposed below the peripheral circuit region PERI. Spatially relative terms, such as “beneath,” “below,” “lower,” “above,” “upper,” “higher” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

The peripheral circuit region PERI may include a substrate 201, impurity regions 205 and device isolation layers 210 in the substrate 201, circuit devices 220 disposed on the substrate 201, a peripheral region insulating layer 290, circuit contact plugs 270, and circuit interconnection lines 280. The peripheral region insulating layer 290, the circuit contact plugs 270, and circuit interconnection lines 280 may be on the substrate 201.

The substrate 201 may have an upper surface extending in the X-direction and the Y-direction. The X-direction and the Y-direction may be parallel with the upper surface of the substrate 201 and intersect with each other. The X-direction and the Y-direction may be perpendicular to each other. In the substrate 201, an active region may be defined by the device isolation layers 210. For example, the active region may be adjacent to (e.g., in between) the device isolation layers 210. Impurity regions 205 including impurities may be disposed in a portion of the active region. The substrate 201 may include a semiconductor material, such as a group IV semiconductor, a group III-V compound semiconductor, and/or a group II-VI compound semiconductor. The substrate 201 may be provided as a bulk wafer or epitaxial layer.

The circuit devices 220 may include planar transistors. Each of the circuit devices 220 may include a circuit gate dielectric layer 222, a spacer layer 224 and a circuit gate electrode 225. Impurity regions 205 may be disposed as source/drain regions in the substrate 201 on both (e.g., opposite) sides of the circuit gate electrode 225.

The peripheral region insulating layer 290 may be disposed on the circuit device 220 on the substrate 201. The peripheral region insulating layer 290 may include a plurality of insulating layers formed in different processes. The peripheral region insulating layer 290 may include an insulating material.

The circuit contact plugs 270 and the circuit interconnection lines 280 may form a circuit interconnection structure electrically connected to the circuit devices 220 and the impurity regions 205. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. For example, an “electrical connection” between element A and element B may include a direct physical connection between element A and element B and/or an indirect physical connection between element A and element B with one or more intervening elements therebetween. The circuit contact plugs 270 may have a cylindrical shape, and the circuit interconnection lines 280 may have a line shape, but are not limited thereto. An electrical signal may be applied to the circuit device 220 by the circuit contact plugs 270 and the circuit interconnection lines 280. In a region not illustrated, the circuit contact plugs 270 may also be connected (e.g., electrically connected) to the circuit gate electrode 225. The circuit interconnection lines 280 may be connected (e.g., electrically connected) to the circuit contact plugs 270, may have a line shape, and may be disposed in a plurality of layers. The circuit contact plugs 270 and the circuit interconnection lines 280 may include a conductive material, for example, tungsten (W), copper (Cu), aluminum (Al), and/or the like, and each component may further include a diffusion barrier. In example embodiments, the number of layers of the circuit contact plugs 270 and the circuit interconnection lines 280 may be varied.

The memory cell region CELL may include a source structure SS (on the peripheral circuit region PERI or on the peripheral region insulating layer 290), gate electrodes 130 stacked on the source structure SS, interlayer insulating layers 120 alternately stacked with the gate electrodes 130, first channel structures CH and second channel structures SH extending in (e.g., penetrating through) at least a portion of the gate electrodes 130, first isolation regions MS extending in (e.g., extending through) at least a portion of the gate electrodes 130, second isolation regions US extending in (e.g., penetrating through) a first upper gate electrode 130U1 of the gate electrodes 130, a horizontal insulating layer 150 disposed between the first channel structures CH and the second channel structures SH, and studs 180 on the second channel structures SH. The memory cell region CELL may further include gate barrier layers 135 extending around (e.g., surrounding) at least a portion of the gate electrodes 130 (in a plan view) and first, second, and third cell region insulating layers 192, 194, and 196 on the gate electrodes 130.

The source structure SS may include a plate layer 101, a first horizontal conductive layer 102, and a second horizontal conductive layer 104 stacked in order. However, in example embodiments, the number of conductive layers included in the source structure SS may be varied.

The plate layer 101 may have a plate shape and may function as at least a portion of a common source line of the semiconductor device 100. The plate layer 101 may have an upper surface extending in the X-direction and the Y-direction. The plate layer 101 may include a conductive material. For example, the plate layer 101 may include a semiconductor material, such as a group IV semiconductor, a group III-V compound semiconductor, and/or a group II-VI compound semiconductor. For example, the group IV semiconductor may include silicon, germanium, and/or silicon-germanium. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be stacked in order on the upper surface of the plate layer 101. The first horizontal conductive layer 102 may function as a portion of a common source line of the semiconductor device 100, and may function as a common source line together with the plate layer 101, for example. As illustrated in FIG. 3B, the first horizontal conductive layer 102 may be directly connected to the first channel layer 140 around the first channel layer 140.

The first and second horizontal conductive layers 102 and 104 may include a semiconductor material, such as polycrystalline silicon. In this case, at least the first horizontal conductive layer 102 may be doped with impurities having the same conductivity as that of the plate layer 101, and the second horizontal conductive layer 104 may be a doped layer or a layer including impurities diffused from the first horizontal conductive layer 102. However, the material of the second horizontal conductive layer 104 is not limited to a semiconductor material, and may be replaced with an insulating layer.

A portion of the gate electrodes 130, for example, the gate electrodes 130 other than the first upper gate electrode 130U1 may be vertically stacked and spaced apart from each other on the plate layer 101 and may form a stack structure together with the interlayer insulating layers 120. The stack structure may include vertically stacked lower and upper stack structures. Alternatively in example embodiments, the stack structure may be configured as a single stack structure. The vertical direction may be the Z-direction that is perpendicular to the X direction and the Y direction. The vertical direction may be perpendicular to the upper surface of the substrate 201.

The gate electrodes 130 may include the first upper gate electrode 130U1 included in string select transistors, a second upper gate electrode 130U2 included in an erase transistor, memory gate electrodes 130M included in a plurality of memory cells, a first lower gate electrode 130L1 included in an erase transistor, and a second lower gate electrode 130L2 included in a ground select transistor. The number of the memory gate electrodes 130M included in the memory cells may be determined depending on capacity of the semiconductor device 100. In example embodiments, each of the number of second upper gate electrode 130U2, the number of first lower gate electrode 130L1, and the number of second lower gate electrode 130L2 may be one to four, or more. In some example embodiments, the positions of the first lower gate electrode 130L1 and the second lower gate electrode 130L2 may be interchanged. In some example embodiments, the second upper gate electrode 130U2 and/or the first lower gate electrode 130L1 may be omitted. In some example embodiments, a portion of the memory gate electrodes 130M may be dummy gate electrodes.

The first upper gate electrode 130U1 and the second lower gate electrode 130L2 may also be referred to as an upper select gate electrode and a lower select gate electrode, respectively. Also, the second lower gate electrode 130L2, the first lower gate electrode 130L1, the memory gate electrodes 130M, and the second upper gate electrode 130U2 disposed in order upwardly may be referred to as first gate electrodes, and the first upper gate electrode 130U1 may be referred to as a second gate electrode. The thickness of the first upper gate electrode 130U1 (in the Z-direction), that is, the second gate electrode may be greater than the thickness of each of the first gate electrodes (in the Z-direction).

The gate electrodes 130 may include a conductive material such as a metal material. For example, the gate electrodes 130 may include tungsten (W), molybdenum (Mo), tantalum (Ta), ruthenium (Ru), niobium (Nb), osmium (Os), zirconium (Zr), iridium (Ir), rhenium (Re) and/or titanium (Ti). The entirety (e.g., each) of the gate electrodes 130 may include a metal material, or at least the first upper gate electrode 130U1 may include a metal material. For example, (each of) the gate electrodes 130 may include the same metal material. In some embodiments, the first upper gate electrode 130U1 may include different material and/or have different material composition from that of the other gate electrodes in the gate electrodes 130 (e.g., the second upper gate electrode 130U2, memory gate electrodes 130M, first lower gate electrode 130L1 and/or the second lower gate electrode 130L2).

The first upper gate electrode 130U1 may include voids VD therein. As illustrated in FIG. 4, the first upper gate electrode 130U1 may be on (e.g., deposited from) side surfaces of second channel structures SH and side surfaces of second isolation regions US. Accordingly, voids VD may be disposed between the second channel structures SH, and between the second channel structures SH and the second isolation regions US. In example embodiments, the relative size and shape of the voids VD may be varied. The voids VD may include air or gas. The first upper gate electrode 130U1 may have an inclined side surface such that a width thereof (e.g., in the X-direction and/or Y-direction) may increase toward the plate layer 101. For example, the side surface and lower surface of the first upper gate electrode 130U1 may have an inclination of less than 90 degrees. For example, the side surface and lower surface of the first upper gate electrode 130U1 may meet each other at an acute angle.

When the first upper gate electrode 130U1 includes a metal material (e.g., more metal material), the resistivity of the first upper gate electrode 130U1 may be reduced as compared to the example in which the first upper gate electrode 130U1 includes a semiconductor material (e.g., more semiconductor material or a semiconductor material only) so that the thickness of the first upper gate electrode 130U1 (in the Z-direction) may be reduced. Accordingly, the vertical level of contact plugs (in the Z-direction) connected (e.g., electrically connected) to the gate electrodes 130 on ends of the gate electrodes 130 (e.g., the first upper gate electrode 130U1) may be reduced together, such that process difficulty of the semiconductor device 100 may be reduced and the overall height of the semiconductor device 100 (in the Z-direction) may be reduced (e.g., lowered). The vertical level may be a relative location (e.g., distance) from a lower surface of the substrate 201 in a vertical direction (e.g., Z-direction). A farther distance from the lower surface of the substrate 201 may be a higher vertical level. A closer distance from the lower surface of the substrate 201 may be a lower vertical level. Also, in the comparative example in which the first upper gate electrode 130U1 includes a semiconductor material (e.g., more semiconductor material or a semiconductor material only), a heat treatment process may be performed to improve (e.g., reduce) the resistivity of the first upper gate electrode 130U1. On the contrary, in the previous example embodiment, the heat treatment process may not be performed for the improved resistivity by the first upper gate electrode 130U1, including a metal material (e.g., more metal material), such that defects such as cracks and warpage caused by the heat treatment process may be reduced (e.g., prevented).

A thickness of the first upper gate electrode 130U1 (in the Z-direction) may be in a range, for example, of about 600 Å to about 900 Å (e.g., 600 Å to 900 Å), or about 700 Å to about 800 Å (e.g., 700 Å to 800 Å). The embodiments of the present disclosures, however, are not limited to the thickness of the first upper gate electrode 130U1.

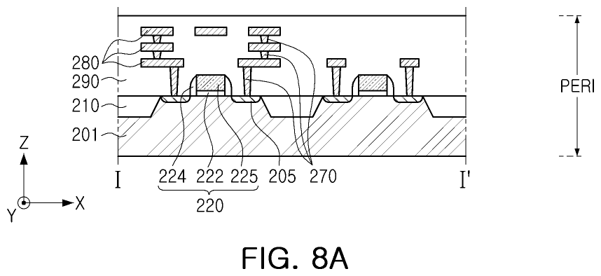

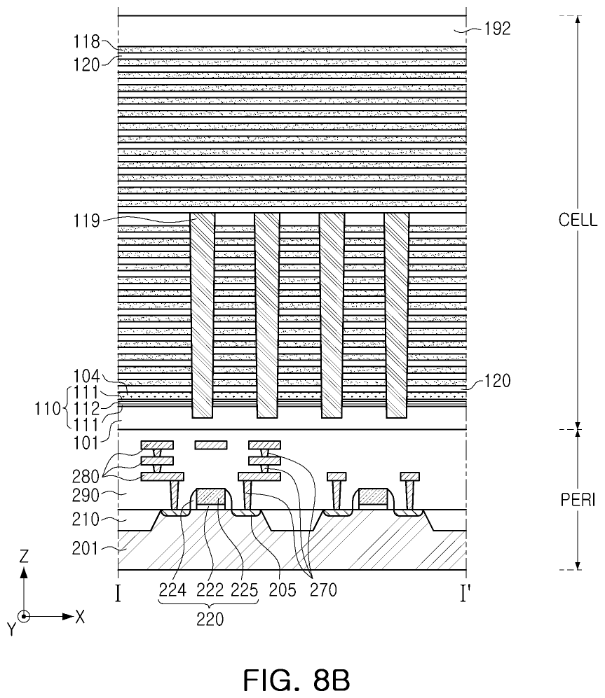

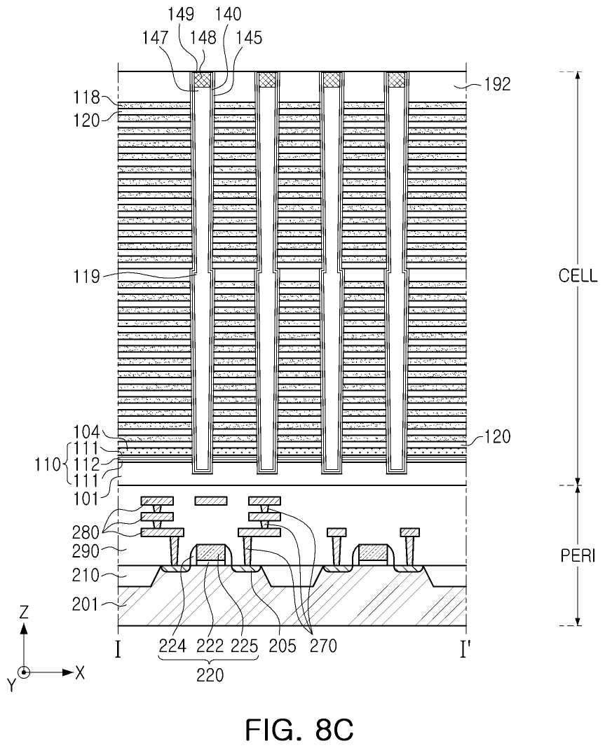

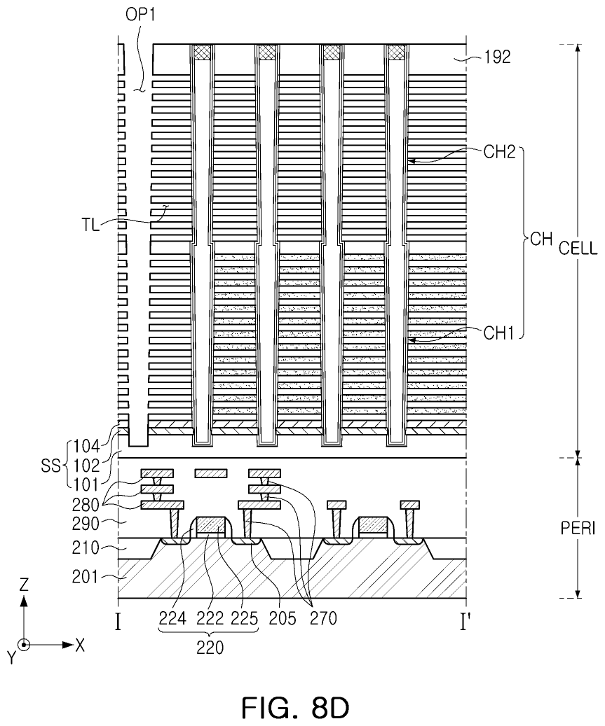

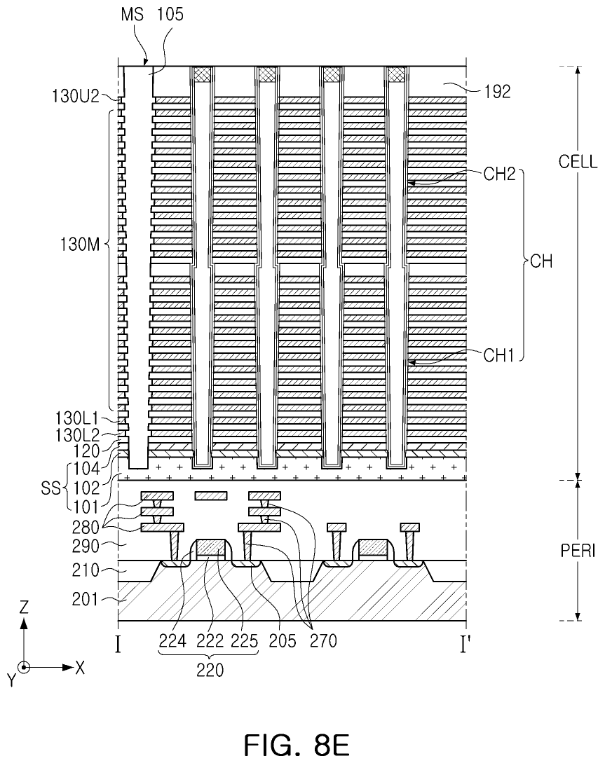

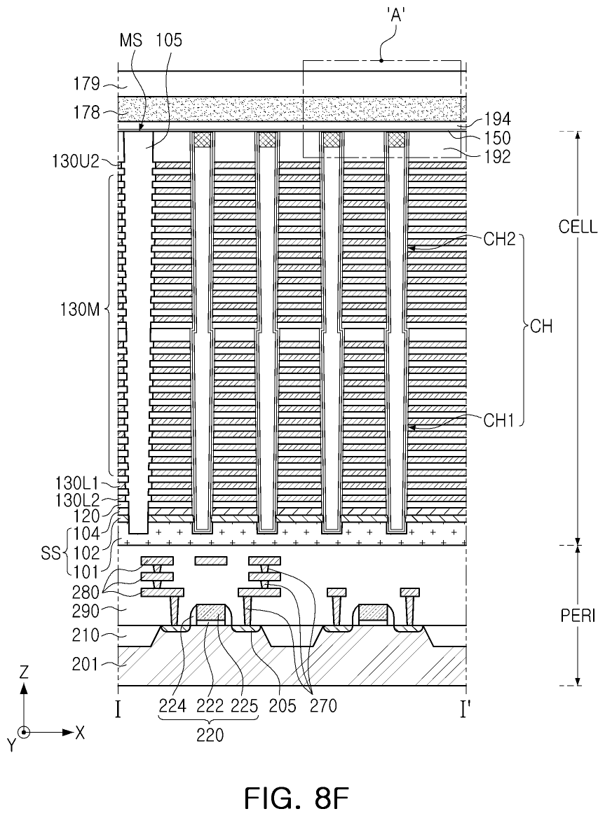

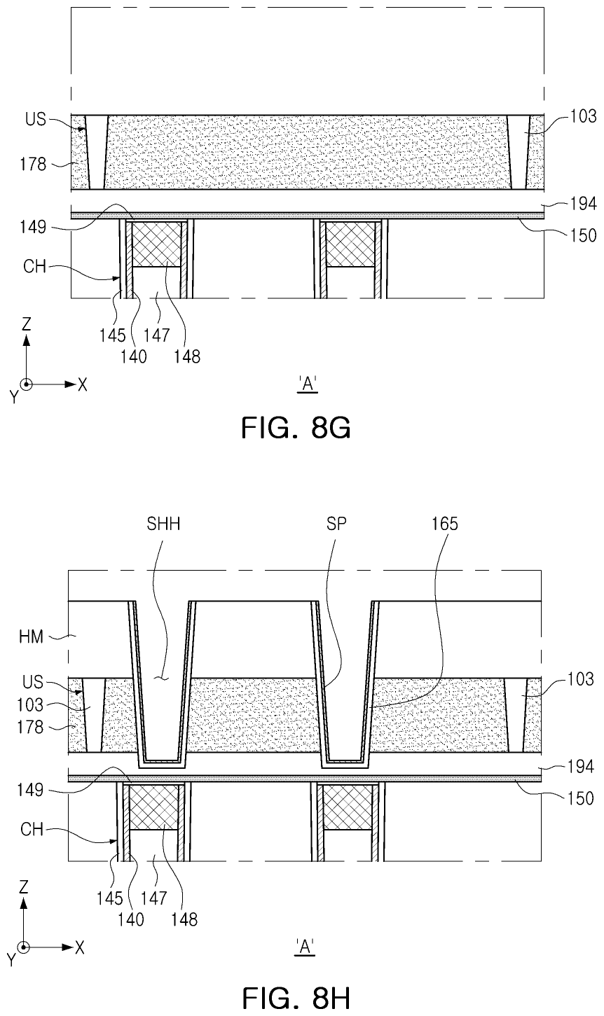

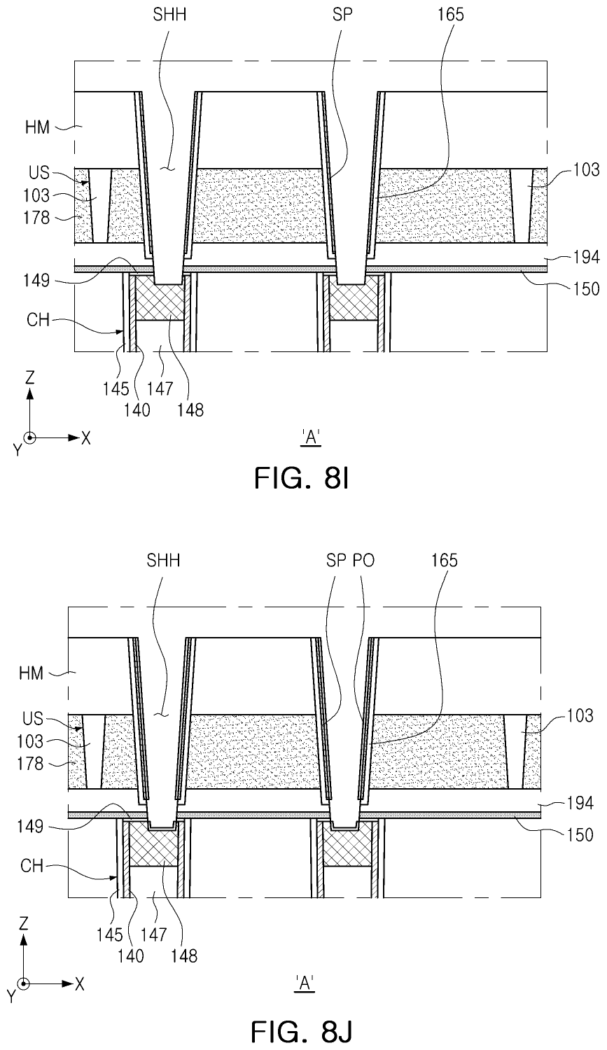

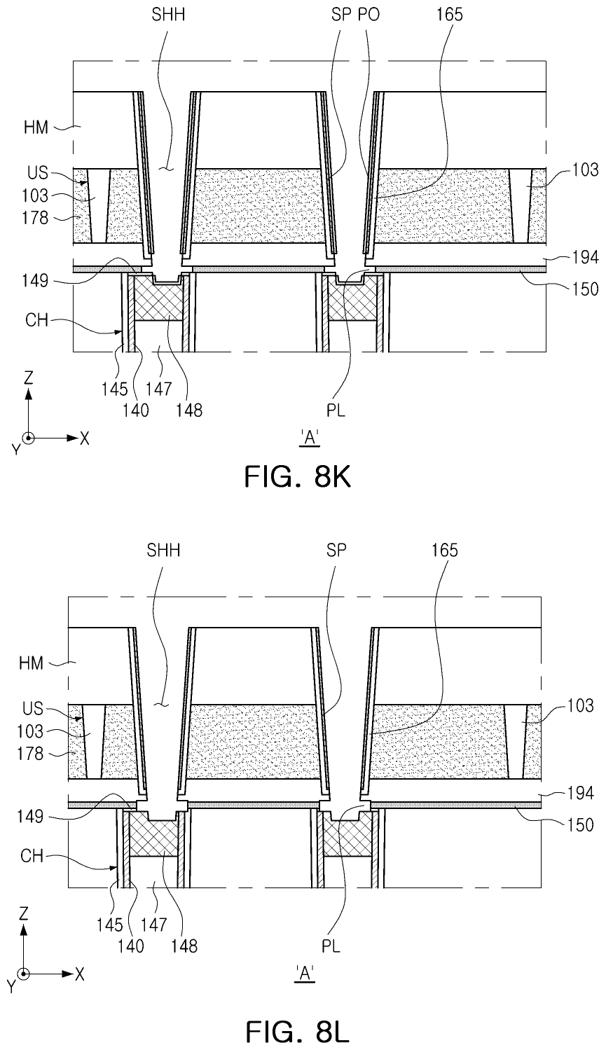

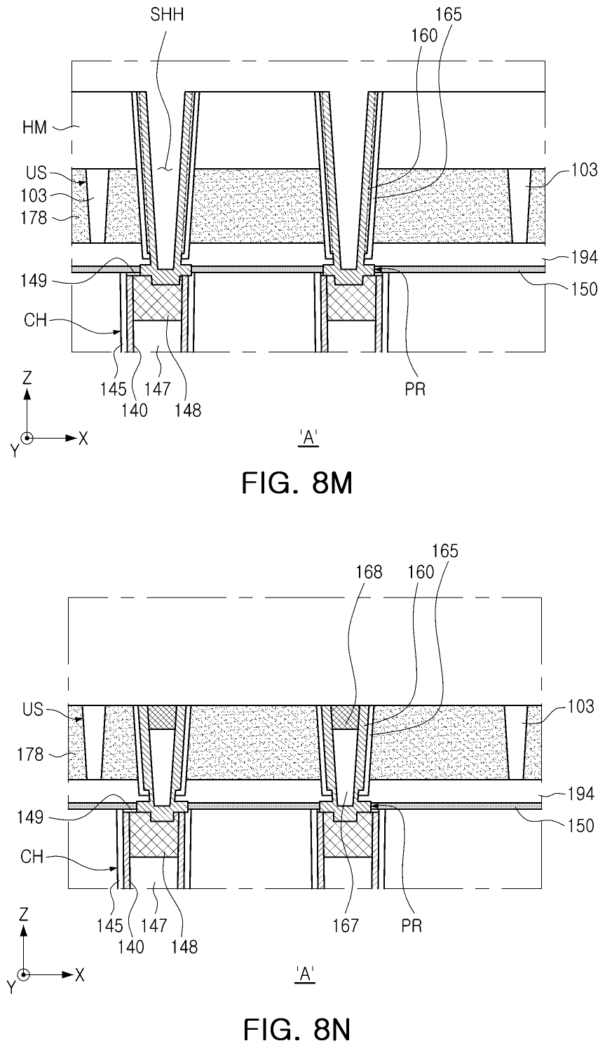

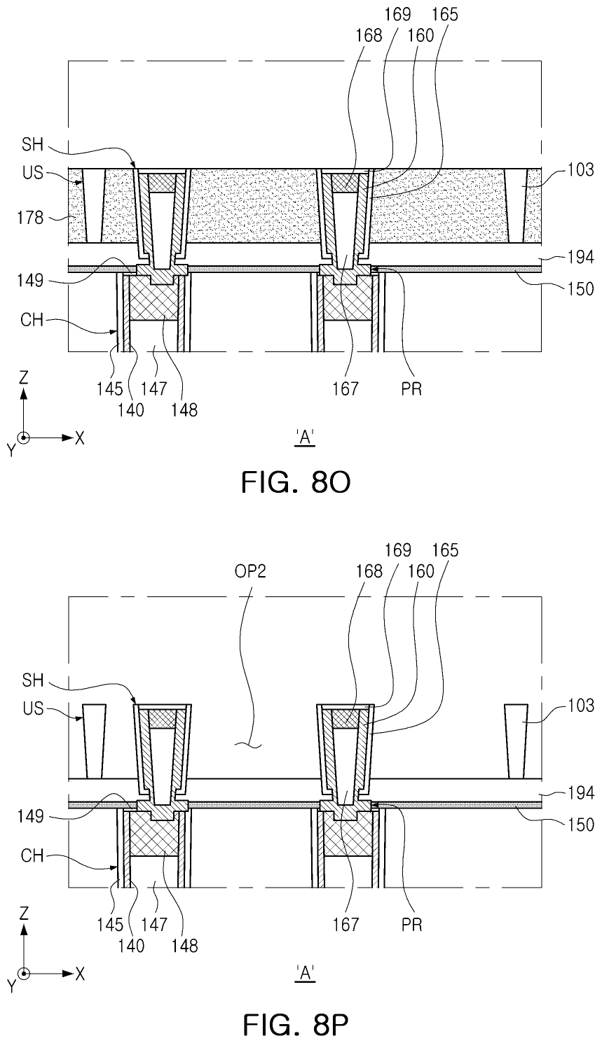

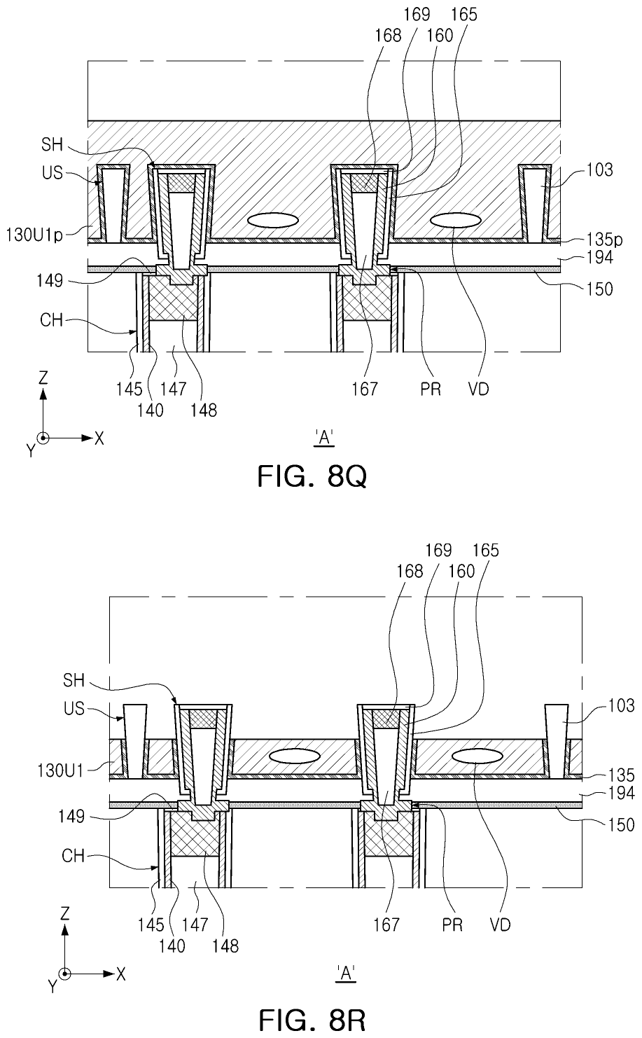

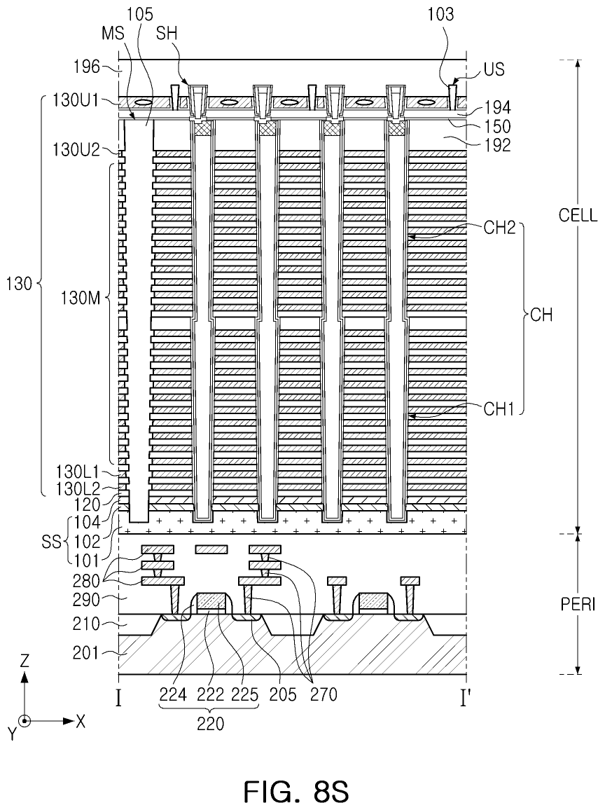

The gate barrier layer 135 may extend around (e.g., surround) the gate electrodes 130 (in a plan view), as illustrated in FIGS. 3A and 3B. The gate barrier layer 135 may be on (e.g., extend around or surround) an upper surface, a lower surface, and a side surface of the gate electrodes 130 other than the first upper gate electrode 130U1. The gate barrier layer 135 may expose an upper surface of the first upper gate electrode 130U1 and may be on (e.g., extend around or surround) lower and side surfaces of the first upper gate electrode 130U1. The arrangement of the gate barrier layer 135 may be due to the process of manufacturing the first upper gate electrode 130U1, which will be described in greater detail with reference to FIGS. 8Q and 8R below. The gate barrier layer 135 on (e.g., covering or overlapping) the first upper gate electrode 130U1 may be in contact with side surfaces of the second channel structures SH and side surfaces of the second isolation regions US (e.g., an upper isolation insulating layer 103, which will be described below). The gate barrier layer 135 may include, for example, tungsten nitride (WN), tantalum nitride (TaN), titanium nitride (TiN), and/or a combination thereof. In some example embodiments, the gate barrier layer 135 may not be provided on the first gate electrodes. As used herein, “an element A overlapping an element B in a direction X” (or similar language) means that there is at least one line that extends in the direction X and intersects both the elements A and B.

The interlayer insulating layers 120 may be disposed between the gate electrodes 130 other than the first upper gate electrode 130U1. Similarly to the gate electrodes 130, the interlayer insulating layers 120 may also be spaced apart from each other in a direction perpendicular to an upper surface of the plate layer 101 (e.g., the Z-direction). The interlayer insulating layers 120 may include an insulating material such as silicon oxide and/or silicon nitride. In example embodiments, the thickness (in the Z-direction) of each of the interlayer insulating layers 120 may be varied.

The first channel structures CH may extend in (e.g., penetrate through) the gate electrodes 130 other than the first upper gate electrode 130U1 in the Z-direction, and may be connected (e.g., electrically connected) to the plate layer 101. The second channel structures SH may extend in (e.g., penetrate through) the first upper gate electrode 130U1 in the Z-direction, and may be physically and electrically connected to the first channel structures CH, respectively. The first channel structures CH may form a memory cell string together with the second channel structures SH, and may be spaced apart from each other while forming rows and columns on the plate layer 101.

As illustrated in FIG. 1, the first channel structures CH may be disposed to form a lattice pattern in an X-Y plane or may be disposed in a zigzag pattern in a direction (e.g., in the X-direction and/or the Y-direction). The second channel structures SH may be disposed on first channel structures CH, respectively. In the example embodiment, at least a portion of the second channel structures SH may not be aligned with the first channel structures CH, and may be shifted or misaligned in a direction (e.g., in the X-direction and/or the Y-direction). For example, the second channel structures SH may overlap the corresponding first channel structures CH in the Z-direction. Herein, misalignment may mean that a center of an element and a center of the other element are disposed at (substantially) different locations in a direction. For example, if a center of element A and a center of element B are at (substantially) different locations in the X-direction, the element A and the element B may be referred to as misaligned in the X-direction. The degrees of misalignments of the second channel structures SH with respect to the corresponding first channel structures CH may be different from each other. For example, distances in the X-direction between the centers of the second channel structures SH and the centers of the corresponding first channel structures CH may be different from each other. For example, referring to FIG. 1, the degree of misalignment (e.g., shifted length or distance between centers) of the first channel structure CH and the corresponding second channel structure SH that are disposed in the leftmost area of the semiconductor device 100 defined by the second isolation regions US may be greater than that of the first channel structure CH and the corresponding second channel structure SH in the center region of the other area (defined by the second isolation regions US) of the semiconductor device 100, wherein the other area may be adjacent to the leftmost area.

Each of the first channel structures CH and the second channel structures SH may have a column shape, and may have an inclined side surface of which a width decreases toward the plate layer 101. A first diameter of first channel structures CH may be larger than a second diameter of second channel structures SH. For example, the first diameter may be in the range of about 60 nm to 100 nm (e.g., 60 nm to 100 nm), and the second diameter may be in the range of from about 40 nm to 80 nm (e.g., 40 nm to 80 nm).

As illustrated in FIGS. 3A and 3B, each of the first channel structures CH may include a first channel layer 140, a first gate dielectric layer 145, a first channel buried insulating layer 147, a first channel pad 148, and a first pad oxide layer 149. The first channel layer 140 may be formed in an annular shape extending around (e.g., surrounding) the first channel buried insulating layer 147 (in a plan view), but in example embodiments, the first channel layer 140 may have a columnar shape such as a cylindrical shape or a prism shape without the first channel buried insulating layer 147 therein. The first channel layer 140 may be connected (e.g., electrically connected) to the first horizontal conductive layer 102 in a lower portion. The first channel layer 140 may include, for example, a semiconductor material such as polycrystalline silicon and/or single crystalline silicon.

The first gate dielectric layer 145 may be disposed between the gate electrodes 130 and the first channel layer 140. Although not specifically illustrated, the first gate dielectric layer 145 may include a tunneling layer, a charge storage layer, and a blocking layer stacked in order on (from) the first channel layer 140. The tunneling layer may tunnel electric charges into the charge storage layer, and may include, for example, silicon oxide (SiO₂), silicon nitride (Si₃N₄), silicon oxynitride (SiON), and/or a combination thereof. The charge storage layer may be configured as a charge trap layer or a floating gate conductive layer. The blocking layer may include, for example, silicon oxide (SiO₂), silicon nitride (Si₃N₄), silicon oxynitride (SiON), a high-K dielectric material, and/or a combination thereof. In example embodiments, at least a portion of the first gate dielectric layer 145 may extend in a horizontal direction (e.g., the X-direction and/or the Y-direction) along the gate electrodes 130.

The first channel pad 148 may be disposed at an upper end of an upper channel structure CH2. The first channel pad 148 may include, for example, doped polycrystalline silicon. The first pad oxide layer 149 may be disposed on upper surfaces of the first channel layer 140 and the first channel pad 148 and may include, for example, silicon oxide.

The first channel structures CH may include vertically stacked (e.g., stacked in the Z-direction) lower and upper channel structures CH1 and CH2. The first channel structures CH may include the lower channel structures CH1 and the upper channel structures CH2 that are connected (e.g., physically and/or electrically connected) to each other, and may have a bent portion due to a difference in width in the connection region between the ower channel structures CH1 and the upper channel structures CH2. However, in example embodiments, the number of channel structures stacked in the Z-direction in the first channel structures CH may be varied. The first channel layer 140, the first gate dielectric layer 145, and the first channel buried insulating layer 147 may consecutively extend between the lower channel structure CH1 and the upper channel structure CH2.

As illustrated in FIG. 3A, each of the second channel structures SH may include a second channel layer 160, a second gate dielectric layer 165, a second channel buried insulating layer 167, a second channel pad 168, and a second pad oxide layer 169. The second channel layer 160 may be formed in an annular shape extending around (e.g., surrounding) the second channel buried insulating layer 167 therein. The second channel layer 160 may extend in (e.g., penetrate through) the horizontal insulating layer 150. In some embodiments, a lower portion of the second channel layer 160 may extend in (E.g., penetrate through) the horizontal insulating layer 150. The second channel layer 160 may have a pad portion PR horizontally expanding in the horizontal insulating layer 150. For example, the second channel layer 160 may horizontally protrude toward the horizontal insulating layer 150. The second channel layer 160 (e.g., the pad portion PR of the second channel layer 160) may be disposed in a horizontally recessed area of the horizontal insulating layer 150. The second channel layer 160 (e.g., a portion of the second channel layer 160 below the pad portion PR) may be disposed in the first channel pad 148 of the first channel structure CH. For example, the second channel layer 160 may partially extend into the first channel pad 148. The second channel layer 160 may be connected (e.g., electrically connected) to the first channel pad 148. The second channel layer 160 may be disposed in a recessed area of the first channel pad 148 below the pad portion PR. The second pad oxide layer 169 may overlap the second channel pad 168 and the second channel layer 160 (in the Z-direction). For example, the second pad oxide layer 169 may cover at least a portion of an upper surface of the second channel pad 168 and an upper surface of the second channel layer 160. The second pad oxide layer 169 may be disposed on an internal side (e.g., an internal side surface) of the second gate dielectric layer 165 and may be in contact with the second gate dielectric layer 165 through a side surface thereof.

The description of materials of the first channel layer 140, the first channel buried insulating layer 147, the first channel pad 148, and the first pad oxide layer 149 may be applied to the description of materials of the second channel layer 160, the second channel buried insulating layer 167, the second channel pad 168, and the second pad oxide layer 169, respectively. The second gate dielectric layer 165 may include, for example, silicon oxide (SiO₂), silicon nitride (Si₃N₄), silicon oxynitride (SiON), a high dielectric constant (high-k) dielectric material, and/or a combination thereof.

The horizontal insulating layer 150 may be disposed between the first channel structures CH and the second channel structures SH and may extend horizontally. In some embodiments, the horizontal insulating layer 150 may overlap the second channel structures SH in a horizontal direction (e.g., the X-direction and/or Y-direction) and may be disposed on the first channel structures CH. The horizontal insulating layer 150 may be disposed between the first upper gate electrode 130U1 and the second upper gate electrode 130U2. The horizontal insulating layer 150 may be used as an etch stop layer when forming the second channel structures SH, and may also be used when forming the pad portion PR of the second channel layer 160.

The horizontal insulating layer 150 may include an insulating material and may include a material different from that of the first and second cell region insulating layers 192 and 194. The horizontal insulating layer 150 may include nitride, and may include, for example, SiN, SiON, SiCN, and/or SiOCN.

The first isolation regions MS may extend in (e.g., penetrate through) the gate electrodes 130 other than the first upper gate electrode 130U1 and may extend in the Y-direction. As illustrated in FIG. 1, the first isolation regions MS may be disposed to be parallel to each other. As illustrated in FIG. 2, the first isolation regions MS may extend in (e.g., penetrate through) the gate electrodes 130 stacked on the plate layer 101, may further extend in (e.g., penetrate through) the first and second horizontal conductive layers 102 and 104, and may be connected to the plate layer 101. Each side surface of the first isolation regions MS may have regions protruding toward the gate electrodes 130 other than the first upper gate electrode 130U1.

Each of the first isolation regions MS may include a gate isolation insulating layer 105. The gate isolation insulating layer 105 may have a shape of which a width may generally decrease toward the plate layer 101 due to a high aspect ratio. The width of the gate isolation insulating layer 105 may not gradually decrease toward the plate layer 101 because of the protruding regions of the first isolation regions MS toward the gate electrodes 130. In some embodiments, widths of the portions of the gate isolation insulating layer 105 protruding toward the gate electrodes 130 may decrease toward the plate layer 101. The gate isolation insulating layer 105 may include an insulating material, for example, silicon oxide, silicon nitride, and/or silicon oxynitride.

As illustrated in FIG. 1, a plurality of second isolation regions US may be disposed between the first isolation regions MS adjacent to each other and may extend in the Y-direction. The second isolation regions US may extend in (e.g., penetrate through) the first upper gate electrode 130U1 disposed at an uppermost portion of the gate electrodes 130. The second isolation regions US may divide the first upper gate electrode 130U1 in the Y-direction. The second isolation regions US may be spaced apart from the first isolation regions MS on a plan view and may not overlap the first isolation regions MS in the Z-direction. In the X-direction, a width of the second isolation regions US may be smaller than a width of the first isolation regions MS and may be smaller than a diameter of the second channel structures SH. The width of the second isolation regions US may be in a range of about 30 nm to about 50 nm (e.g., 30 nm to 50 nm), for example.

Upper surfaces of the second isolation regions US may be disposed on substantially the same level (e.g., the same vertical level) as upper surfaces of the second channel structures SH. For example, the upper surfaces of the second isolation regions US may be disposed at the same distance from the plate layer 101 as the upper surfaces of the second channel structures SH in the Z-direction. Side surfaces of the second isolation regions US may have a different shape from those of the first isolation regions MS. Specifically, side surfaces of the second isolation regions US may extend, with a constant slope, toward the plate layer 101 without a region protruding horizontally toward the first upper gate electrode 130U1. The side surfaces of the second isolation regions US may be substantially planar. The side surfaces of the second isolation regions US may be formed as above because the second isolation regions US may be formed before the first upper gate electrode 130U1, which will be described in greater detail with reference to FIGS. 8G to 8R below.

Each of the second isolation regions US may include an upper isolation insulating layer 103. The upper isolation insulating layer 103 may include an insulating material, for example, silicon oxide, silicon nitride, and/or silicon oxynitride.

The studs 180 may be included in a cell interconnection structure electrically connected to memory cells in a memory cell region CELL. The studs 180 may be connected (e.g., electrically and physically connected) to the second channel structures SH, and may be electrically connected to the first channel structures CH. The studs 180 may have a hole shape, may extend in (e.g., penetrate through) the second pad oxide layers 169 of the second channel structures SH, and may be (at least partially) disposed in a recessed area of the second channel pads 168. However, whether the second channel pads 168 are recessed and the recess depth thereof may be varied in example embodiments. The studs 180 may electrically connect the first channel structures CH and the second channel structures SH to bit lines that are not illustrated. The studs 180 may include metal, for example, tungsten (W), copper (Cu), or aluminum (Al).

The first, second, and third cell region insulating layers 192, 194, and 196 may be disposed on the gate electrodes 130. The first cell region insulating layer 192 may be on (e.g., cover or overlap) the second upper gate electrode 130U2, the second cell region insulating layer 194 may be on (e.g., cover or overlap) the horizontal insulating layer 150, and the third cell region insulating layer 196 may be on (e.g., cover or overlap) the first upper gate electrode 130U1. The first, second, and third cell region insulating layers 192, 194, and 196 may include an insulating material, and each of the layers may include a plurality of insulating layers.

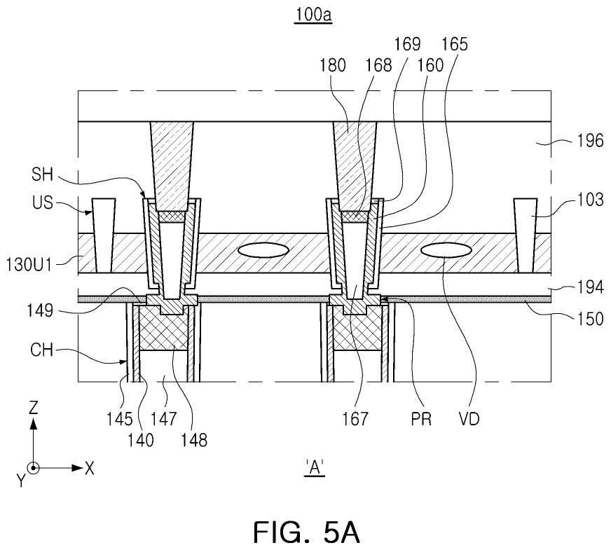

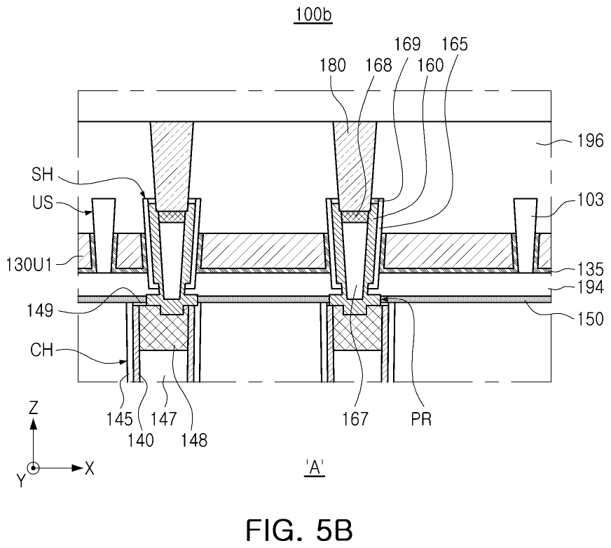

FIGS. 5A and 5B are enlarged views illustrating a portion of a semiconductor device according to an example embodiment. FIGS. 5A and 5B each illustrate a region corresponding to FIG. 3A.

Referring to FIG. 5A, in a semiconductor device 100a, the gate barrier layer 135 (see FIG. 3A) extending around (e.g., surrounding) the first upper gate electrode 130U1 may be omitted. Accordingly, the first upper gate electrode 130U1 may be in contact with side surfaces of the second channel structures SH and side surfaces of the second isolation regions US. In the example embodiment, the gate barrier layers 135 (see FIG. 3B) on the gate electrodes 130 that are disposed below the first upper gate electrode 130U1 may be omitted.

Referring to FIG. 5B, in a semiconductor device 100b, the first upper gate electrode 130U1 may not include voids VD (see FIG. 3A) therein. The voids VD may not be formed as in the example embodiment depending on a distance between the second channel structures SH, a material of the first upper gate electrode 130U1, and deposition conditions of the first upper gate electrode 130U1.

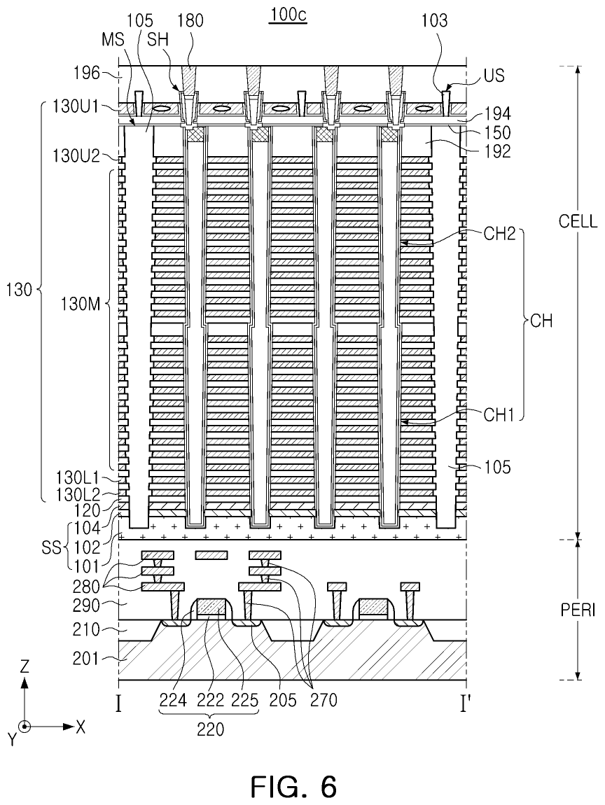

FIG. 6 is a cross-sectional view illustrating a semiconductor device according to an example embodiment.

Referring to FIG. 6, in a semiconductor device 100c, the arrangement relationship between the first isolation regions MS and the second isolation regions US and the arrangement relationship between the first channel structures CH and the second channel structures SH may be different from those in the example embodiment in FIG. 2.

At least one of the second isolation regions US may be disposed on the first isolation regions MS and may overlap the first isolation regions MS in the Z-direction. In some example embodiments, the first isolation regions MS may further extend upwardly to extend in (e.g., penetrate through) the first upper gate electrode 130U1. In this case, the second isolation regions US on the first isolation regions MS may be omitted.

In some embodiments, a second structure SH among the second structures SH may be misaligned with respect to a corresponding first channel structure CH in a direction, and the other second structure SH among the second structures SH may be misaligned with respect to the other corresponding first channel structure CH in the other direction (e.g., the opposite direction). For example, a second structure SH among the second channel structures SH may be misaligned on a left side of a corresponding first channel structure CH among the first channel structures CH, and the other second structure SH among the second channel structures SH may be misaligned on a right side of the other corresponding first channel structure CH among the first channel structures CH.

In example embodiments, the arrangement of the first isolation regions MS and the second isolation regions US, and the misalignment of the first channel structures CH and the second channel structures SH may be varied.

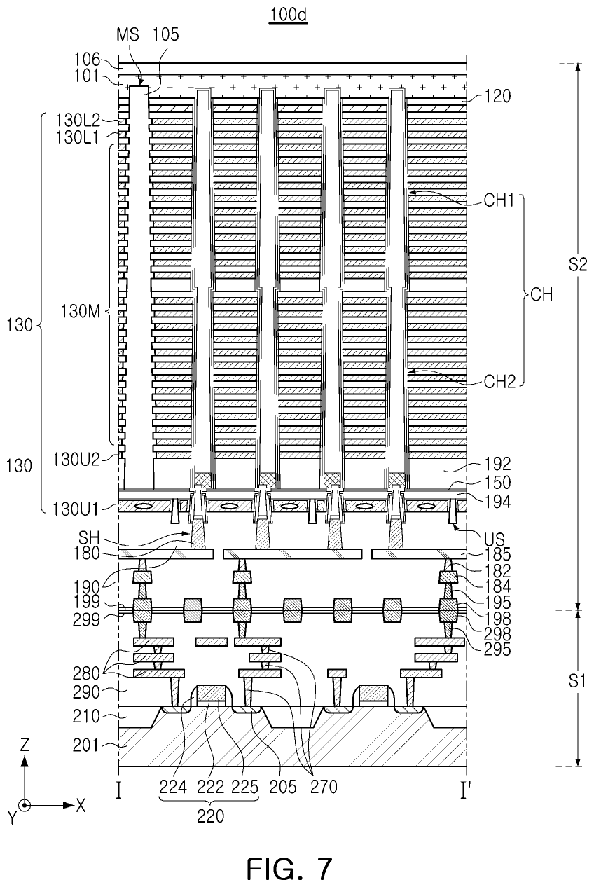

FIG. 7 is a cross-sectional view illustrating a semiconductor device according to an example embodiment.

Referring to FIG. 7, a semiconductor device 100d may include a first semiconductor structure S1 and a second semiconductor structure S2 bonded by a wafer bonding method.

The description of the peripheral circuit region PERI described above with reference to FIGS. 1 and 2 may be applied to the first semiconductor structure S1. However, the first semiconductor structure S1 may further include first bonding vias 295, first bonding metal layers 298, and first bonding insulating layer 299, which are bonding structures. The first bonding vias 295 may be disposed above the uppermost circuit interconnection lines 280 and may be connected (e.g., electrically connected) to the circuit interconnection lines 280. At least a portion of the first bonding metal layers 298 may be connected (e.g., electrically connected) to the first bonding vias 295 on the first bonding vias 295. The first bonding metal layers 298 may be connected (e.g., electrically connected) to the second bonding metal layers 198 of the second semiconductor structure S2. The first bonding metal layers 298, together with the second bonding metal layers 198, may provide an electrical connection path according to bonding between the first semiconductor structure S1 and the second semiconductor structure S2. A portion of the first bonding metal layers 298 may be connected to the lower circuit interconnection lines 280 and may disposed only for bonding. The first bonding vias 295 and the first bonding metal layers 298 may include a conductive material such as copper (Cu). The first bonding insulating layer 299 may be disposed around (e.g., may extend around) the first bonding metal layers 298. The first bonding insulating layer 299 may also be configured to function as a diffusion barrier of the first bonding metal layers 298, and may include, for example, SiN, SiON, SiCN, SiOC, SiOCN, and/or SiO.

Regarding the description of the memory cell region CELL described above with reference to FIGS. 1 to 4 may be applied to the second semiconductor structure S2, unless otherwise indicated. The second semiconductor structure S2 may further include the bit lines 185, the lower contact plugs 182, and the cell interconnection lines 184, which are cell interconnection structures, and may further include the second bonding vias 195, the second bonding metal layers 198, and the second bonding insulating layer 199, which are bonding structures. The second semiconductor structure S2 may further include a passivation layer 106 on (e.g., covering or overlapping) an upper surface of the plate layer 101.

The bit lines 185 may be connected (e.g., electrically connected) to the studs 180, the lower contact plugs 182 may be connected (e.g., electrically connected) to the bit lines 185, and the cell interconnection lines 184 may be connected (e.g., electrically connected) to the lower contact plugs 182. However, in example embodiments, the number of layers of the contact plugs and the interconnection lines included in the cell interconnection structure and arrangements thereof may be varied. The bit lines 185, lower contact plugs 182, and the cell interconnection lines 184 may include a conductive material, and may include, for example, tungsten (W), aluminum (Al), and/or copper (Cu).

The second bonding vias 195 and the second bonding metal layers 198 may be disposed below the lowermost cell interconnection lines 184. The second bonding vias 195 may connect (e.g., electrically connect) the cell interconnection lines 184 to the second bonding metal layers 198, and the second bonding metal layers 198 may be bonded to the first bonding metal layers 298 of the first semiconductor structure S1. The second bonding insulating layer 199 may be bonded and connected to the first bonding insulating layer 299 of the first semiconductor structure S1. The second bonding vias 195 and the second bonding metal layers 198 may include a conductive material such as copper (Cu). The second bonding insulating layer 199 may include, for example, SiO, SiN, SiCN, SiOC, SiON, and/or SiOCN.

The first and second semiconductor structures S1 and S2 may be bonded by bonding between the first bonding metal layers 298 and the second bonding metal layers 198 and bonding between the first bonding insulating layer 299 and the second bonding insulating layer 199. The bonding between the first bonding metal layers 298 and the second bonding metal layers 198 may be, for example, copper (Cu)-to-copper (Cu) bonding, and the bonding between the first bonding insulating layer 299 and the second bonding insulating layer 199 may be, for example, dielectric-dielectric bonding such as SiCN-to-SiCN bonding. The first and second semiconductor structures S1 and S2 may be bonded by hybrid bonding including copper (Cu)-to-copper (Cu) bonding and dielectric-to-dielectric bonding.

The passivation layer 106 may be disposed on an upper surface of the plate layer 101 and may protect the semiconductor device 100d. The passivation layer 106 may include an insulating material, for example, silicon oxide, silicon nitride, and/or silicon carbide, and may include a plurality of insulating layers in example embodiments.

In the example embodiment, the second semiconductor structure S2 may not include the first and second horizontal conductive layers 102 and 104 (see FIG. 2). An upper end of the first channel structures CH may expose the first channel layers 140 (see FIG. 3B), and the first channel structures CH (the first channel layers 140) may be directly connected (e.g., electrically connected) to the plate layer 101. However, the electrical connection between the first channel structures CH and the common source line may be varied in the example embodiments, and the first channel structures CH and the source structure SS may have the same structure as in the example embodiment in FIG. 2.

FIGS. 8A to 8S are cross-sectional views illustrating a method of manufacturing a semiconductor device according to an example embodiment. FIGS. 8A to 8F, and 8S illustrate a region corresponding to FIG. 2, and FIGS. 8G to 8R illustrate a region corresponding to FIG. 3A.

Referring to FIG. 8A, circuit devices 220, a circuit interconnection structure (e.g., the circuit contact plugs 270 and the circuit interconnection lines 280), and a peripheral region insulating layer 290 included in a peripheral circuit region PERI may be formed on a substrate 201.

First, the device isolation layers 210 may be formed in the substrate 201, and a circuit gate dielectric layer 222 and a circuit gate electrode 225 may be formed in order on the substrate 201. The device isolation layers 210 may be formed by, for example, a shallow trench isolation (STI) process. The circuit gate dielectric layer 222 and the circuit gate electrode 225 may be formed using atomic layer deposition (ALD) and/or chemical vapor deposition (CVD). The circuit gate dielectric layer 222 may include, for example, silicon oxide, and the circuit gate electrode 225 may include, for example, polycrystalline silicon and/or a metal silicide layer, but an example embodiment thereof is not limited thereto. Thereafter, a spacer layer 224, and impurity regions 205 may be formed on both (e.g., opposite) side surfaces of the circuit gate dielectric layer 222 and the circuit gate electrode 225. In example embodiments, the spacer layer 224 may include a plurality of layers. The impurity regions 205 may be formed by performing an ion implantation process.

Among the circuit interconnection structures, the circuit contact plugs 270 may be formed by partially forming the peripheral region insulating layer 290, removing a portion by etching, and filling a conductive material therein. The circuit interconnection lines 280 may be formed, for example, by depositing a conductive material and patterning the material.

The peripheral region insulating layer 290 may include a plurality of insulating layers. The peripheral region insulating layer 290 may be formed as a part of each process forming the other elements of the circuit interconnection structure (e.g., the circuit contact plugs 270 and the circuit interconnection lines 280). Accordingly, a peripheral circuit region PERI may be formed.

Referring to FIG. 8B, a memory cell region CELL including a plate layer 101, a horizontal sacrificial layer 110, and a second horizontal conductive layer 104 may be formed on the peripheral circuit region PERI. The plate layer 101, the horizontal sacrificial layer 110, and the second horizontal conductive layer 104 may be sequentially formed on the peripheral region insulating layer 290. A lower mold structure may be formed by alternately stacking lower sacrificial insulating layers 118 and interlayer insulating layers 120 on the second horizontal conductive layer 104. Lower channel sacrificial layers 119 may be formed in the lower mold structure, and an upper mold structure may be formed by alternately stacking the lower sacrificial insulating layers 118 and the interlayer insulating layers 120 on the lower mold structure and/or the lower channel sacrificial layers 119.

The plate layer 101 may be formed on the peripheral region insulating layer 290. The plate layer 101 may include, for example, polycrystalline silicon and may be formed by a CVD process. Polycrystalline silicon included in the plate layer 101 may include impurities.

The horizontal sacrificial layer 110 may include the first and second horizontal insulating layers 111 and 112. The first and second horizontal insulating layers 111 and 112 may be alternately stacked on the plate layer 101. The horizontal sacrificial layer 110 may be replaced with the first horizontal conductive layer 102 in FIG. 2 through a subsequent process. The first horizontal insulating layer 111 may include a material different from that of the second horizontal insulating layer 112. For example, the first horizontal insulating layer 111 may include the same material as that of the interlayer insulating layers 120, and the second horizontal insulating layer 112 may include the same material as that of the lower sacrificial insulating layers 118. A second horizontal conductive layer 104 may be formed on the horizontal sacrificial layer 110.

The lower mold structure may be formed on the second horizontal conductive layer 104 at a vertical level at which the first channel structures CH1 (see FIG. 2) of channel structures CH (see FIG. 2) are disposed. For example, a vertical level of an upper surface of the lower mold structure may be (substantially) the same as that of an upper surface of the first channel structures CH1.

The lower sacrificial insulating layers 118 may be replaced with a portion of gate electrodes 130 (see FIG. 2) through a subsequent process. The lower sacrificial insulating layers 118 may include a material different from that of the interlayer insulating layers 120, and may have an etch selectivity (at least under specific etching conditions) with respect to the interlayer insulating layers 120. For example, the interlayer insulating layer 120 may include silicon oxide and/or silicon nitride, and the lower sacrificial insulating layers 118 may include a material different from that of the interlayer insulating layer 120. For example, the lower sacrificial insulating layers 118 may include silicon, silicon oxide, silicon carbide, and/or silicon nitride. In example embodiments, the interlayer insulating layers 120 may not have the same thickness. The thicknesses of the interlayer insulating layers 120 and the lower sacrificial insulating layers 118 and the numbers of the interlayer insulating layers 120 and the lower sacrificial insulating layers 118 may be varied from the illustrated examples.

The lower channel sacrificial layers 119 may be formed in a position corresponding to the first channel structures CH1. The lower channel sacrificial layers 119 may be formed by forming holes to extend in (e.g., penetrate through) the lower mold structure, depositing a material forming the lower channel sacrificial layers 119 in the holes, and performing a planarization process. The lower channel sacrificial layers 119 may include, for example, polycrystalline silicon.

The upper mold structure may be formed on the lower mold structure at a vertical level at which the second channel structures CH2 (see FIG. 2) of channel structures CH are disposed. For example, a vertical level of an upper surface of the upper mold structure may be (substantially) the same as that of an upper surface of the second channel structures CH2. The upper mold structure may be formed by alternately stacking the lower sacrificial insulating layers 118 and the lower interlayer insulating layers 120 in the same manner as the lower mold structure. A first cell region insulating layer 192 may be formed on the uppermost lower sacrificial insulating layers 118.

Referring to FIG. 8C, the channel structures CH extending in (e.g., penetrating through) the lower mold structure and the upper mold structure may be formed.

First, upper channel sacrificial layers extending in (e.g., penetrating through) the upper mold structure may be formed. The upper channel sacrificial layers may be formed in positions corresponding to upper channel structures CH2. The upper channel sacrificial layers may be formed to be connected to the lower channel sacrificial layers 119, respectively.

The channel structures CH may be formed by forming lower channel holes by removing portions of the lower channel sacrificial layers 119 and the upper channel sacrificial layers, depositing at least a portion of a first gate dielectric layer 145, a first channel layer 140, and a first channel buried insulating layer 147, and a first channel pad 148 in order in the lower channel holes, and forming a first pad oxide layer 149.

The first gate dielectric layer 145 may be formed to have a uniform thickness (e.g., thickness in the X-direction or the Y-direction) using an ALD and/or CVD process. In this process, the entirety or a portion of the first gate dielectric layer 145 may be formed, and a portion extending (substantially) perpendicularly to the plate layer 101 along channel structures CH (e.g., along an inner side surface of the lower channel holes) may be formed in this process. The first channel layer 140 may be formed on the first gate dielectric layer 145 in the lower channel holes. The first channel buried insulating layer 147 may be formed to fill remaining portions of the lower channel holes and may include, for example, an insulating material. The first channel pad 148 may be formed after partially removing the first channel buried insulating layer 147. The first channel pad 148 may include a conductive material, for example polycrystalline silicon. The first pad oxide layer 149 may be formed by oxidizing the first channel pad 148 and the first channel layer 140 exposed upwardly.

Referring to FIG. 8D, the first openings OP1 may be formed, a first horizontal conductive layer 102 may be formed, and lower sacrificial insulating layers 118 may be removed.

The first openings OP1 may be formed at positions of the first isolation regions MS (see FIG. 2). The first openings OP1 may extend in (e.g., penetrate through) the lower sacrificial insulating layers 118 and the interlayer insulating layers 120 and may extend to the plate layer 101. While forming sacrificial spacer layers in the first openings OP1, by performing an etch-back process, the horizontal sacrificial layer 110 may be selectively removed, and a portion of the exposed first gate dielectric layer 145 may also be removed together. After forming a first horizontal conductive layer 102 by depositing a conductive material in the region from which the horizontal sacrificial layer 110 is removed, the sacrificial spacer layers may be removed from the first openings OP1.

The lower sacrificial insulating layers 118 may be selectively removed with respect to the interlayer insulating layers 120, the second horizontal conductive layer 104, and the first channel structures CH using, for example, wet etching. The tunnel portions TL may be formed in regions from which the lower sacrificial insulating layers 118 are removed.

Referring to FIG. 8E, the second lower gate electrode 130L2, the first lower gate electrode 130L1, the memory gate electrodes 130M, and the second upper gate electrode 130U2 may be formed, and the first isolation regions MS may be formed.

In this process, the first gate electrodes (e.g., the second lower gate electrode 130L2, the first lower gate electrode 130L1, the memory gate electrodes 130M, and the second upper gate electrode 130U2) extending around (e.g., surrounding) the first channel structures CH in a plan view may be formed. The first gate electrodes may be formed by depositing a conductive material in the tunnel portions TL. Before forming the first gate electrodes, gate barrier layers 135 may be first formed as illustrated in FIG. 3B. In some example embodiments, a portion of the first gate dielectric layer 145 may be preferentially formed before forming the gate barrier layers 135. After forming the first gate electrodes, a first isolation region MS may be formed by forming a gate isolation insulating layer 105 in the first openings OP1.

Referring to FIG. 8F, a horizontal insulating layer 150 may be formed, and an upper sacrificial insulating layer 178 and an upper interlayer insulating layer 179 may be formed on the horizontal insulating layer 150.

The horizontal insulating layer 150 may be formed on (e.g., to cover or overlap) upper surfaces of the first channel structures CH and upper surfaces of the first isolation regions MS. Thereafter, a second cell region insulating layer 194 may be formed on the horizontal insulating layer 150.

The upper sacrificial insulating layer 178 may include a material different from that of the second cell region insulating layer 194 and the upper interlayer insulating layer 179. For example, the second cell region insulating layer 194 and the upper interlayer insulating layer 179 may include silicon oxide, and the upper sacrificial insulating layer 178 may include silicon nitride.

Referring to FIG. 8G, the second isolation regions US may be formed.

First, in a position corresponding to the second isolation regions US, trenches may be formed by partially removing the upper sacrificial insulating layer 178 and the upper interlayer insulating layer 179, an insulating material included in the upper isolation insulating layer 103 may be filled in the trenches, a planarization process such as chemical mechanical polishing (CMP) may be performed, thereby removing the entirety of the upper interlayer insulating layer 179. During the planarization process, the upper sacrificial insulating layer 178 may be used as a planarization stop layer. Accordingly, the second isolation regions US each including the upper isolation insulating layer 103 may be formed.

Referring to FIG. 8H, after forming a hard mask layer HM on the upper sacrificial insulating layer 178 and forming upper channel holes SHH, a second gate dielectric layer 165 and a spacer layer SP may be formed in the upper channel holes SHH (e.g., on a side surface and a lower surface of the upper channel holes SHH).

The upper channel holes SHH may be formed in positions corresponding to the second channel structures SH (see FIG. 3A). The upper channel holes SHH may extend in (e.g., penetrate through) the upper sacrificial insulating layer 178 and may expose the second cell region insulating layer 194 through lower and/or side surfaces of the upper channel holes SHH. In some example embodiments, the upper channel holes SHH may be formed such that the horizontal insulating layer 150 is exposed through the lower and/or side surfaces of the upper channel holes SHH.

The second gate dielectric layer 165 and the spacer layer SP may be formed in order in the upper channel holes SHH. In this process, the spacer layer SP may also be formed on the lower and/or side surfaces of the upper channel holes SHH. The spacer layer SP may form a portion of the second channel layer 160 (see FIG. 3A) through a subsequent process. The spacer layer SP may include a semiconductor material, such as polycrystalline silicon.

Referring to FIG. 8I, the upper channel holes SHH may further extend downwardly to expose the first channel pads 148.

The upper channel holes SHH may extend downwardly by performing an etch-back process using the spacer layer SP. The upper channel holes SHH may penetrate through the spacer layer SP, the second gate dielectric layer 165, the second cell region insulating layer 194, and the horizontal insulating layer 150, may further penetrate through the first pad oxide layers 149 of the first channel structures CH, and may partially recess the first channel pads 148. However, whether the first channel pads 148 are recessed and the recess depth of the first channel pads 148 may be varied in example embodiments.

Referring to FIG. 8J, oxide layers PO may be formed by oxidizing semiconductor material layers exposed by the upper channel holes SHH.

The semiconductor material layers exposed by the upper channel holes SHH may include the spacer layer SP and the first channel pads 148. The oxide layers PO may include, for example, silicon oxide layers.

Referring to FIG. 8K, a portion of the horizontal insulating layer 150 exposed by the upper channel holes SHH may be removed.

The horizontal insulating layer 150 may be selectively removed by, for example, a wet etching process, thereby forming the pad tunnel portions PL. Accordingly, the upper channel holes SHH may have pad tunnel portions PL extending horizontally on the first channel pads 148. During this process, the oxide layers PO may prevent the semiconductor material layers (e.g., the spacer layer SP and the first channel pads 148) from being damaged by an etchant.

Referring to FIG. 8L, the oxide layers PO may be removed.

The oxide layers PO may be selectively removed by, for example, a wet etching process. In this process, the first pad oxide layers 149 and the second cell region insulating layer 194 may be partially removed together with the oxide layers PO. Accordingly, a height (vertical level) of the pad tunnel portions PL may increase (heightened). However, the degree to which the height of pad tunnel portions PL changes may be varied in example embodiments.

Referring to FIG. 8M, second channel layers 160 may be formed.

The second channel layers 160 may be formed by depositing a semiconductor material, such as polycrystalline silicon, on (e.g., to cover or overlap) the first channel pads 148 exposed through the upper channel holes SHH. The semiconductor material may also be formed on spacer layers SP on internal side surfaces of the upper channel holes SHH, and the spacer layers SP may form the second channel layers 160 together with the semiconductor material. The semiconductor material may fill the pad tunnel portions PL, and accordingly, the second channel layers 160 may have pad portions PR. Subsequently, a heat treatment process may be performed such that crystallinity of the second channel layers 160 may be improved.

Referring to FIG. 8N, the second channel buried insulating layers 167 and the second channel pads 168 may be formed.

The second channel buried insulating layers 167 may be formed in (to fill remaining portions of) the upper channel holes SHH. Thereafter, the second channel buried insulating layers 167 may be partially removed from the upper end, the second channel pads 168 may be formed thereon, and a CMP process may be performed. In the CMP process, an upper sacrificial insulating layer 178 may be used as a CMP stop layer.

Referring to FIG. 8O, second pad oxide layers 169 may be formed.

The second pad oxide layers 169 may be formed by oxidizing the exposed upper portions (e.g., the upper surfaces) of the second channel pads 168 and the second channel layers 160. The thickness of the second pad oxide layers 169 may be in the range of, for example, about 20 Å to about 40 Å (e.g., 20 Å to 40 Å). Accordingly, the second channel structures SH may finally be formed.

Referring to FIG. 8P, the second opening OP2 may be formed by removing the upper sacrificial insulating layer 178.

The upper sacrificial insulating layer 178 may be removed by, for example, a wet etching process, and may be selectively removed with respect to the second isolation regions US, the second channel structures SH, and the second cell region insulating layer 194. When the upper sacrificial insulating layer 178 is removed, the second pad oxide layers 169 may protect the second channel pads 168 and the second channel layers 160 from being damaged by the etchant.

Referring to FIG. 8Q, a preliminary gate barrier layer 135p and a first preliminary upper gate electrode 130U1p may be formed.

The preliminary gate barrier layer 135p may be formed on (e.g., to cover or overlap) side surfaces and upper surfaces of the second channel structures SH exposed by the second opening OP2, and side surfaces and upper surfaces of the second isolation regions US. A material included in the first upper gate electrode 130U1 (see FIG. 3A) may be deposited on the preliminary gate barrier layer 135p to form the first preliminary upper gate electrode 130U1p. The material included in the first upper gate electrode 130U1 may be a metal material. The voids VD may be formed in the first preliminary upper gate electrode 130U1p. In example embodiments, the size and the shape of the voids VD may be varied.

Referring to FIG. 8R, gate barrier layers 135 and first upper gate electrodes 130U1 may be formed.

The gate barrier layers 135 and the first upper gate electrodes 130U1 may be formed by partially removing the preliminary gate barrier layer 135p and the first preliminary upper gate electrode 130U1p from upper portions thereof using, for example, a wet etching process. Accordingly, upper regions of the second isolation regions US and the second channel structures SH may protrude above (protrude upwardly from) an upper surface of first upper gate electrodes 130U1. A portion of the gate barrier layers 135 may be removed and may remain only on side surfaces and lower surfaces of the first upper gate electrodes 130U1.

In the example embodiment, since the first upper gate electrodes 130U1 include a metal material, differently from a case in which the gate electrodes are formed of a semiconductor material, a heat treatment process may not be performed after deposition. Therefore, structural defects caused by the heat treatment process may be prevented.

Referring to FIG. 8S, a third cell region insulating layer 196 may be formed.

The third cell region insulating layer 196 may be formed on (e.g., to cover or overlap) the first upper gate electrodes 130U1, the second isolation regions US, and the second channel structures SH. The third cell region insulating layer 196 may have a flat upper surface by a planarization process.

Thereafter, referring to FIG. 2 together, by forming studs 180 connected (e.g., electrically connected) to the upper ends of the second channel structures SH, the semiconductor device 100 may be manufactured.

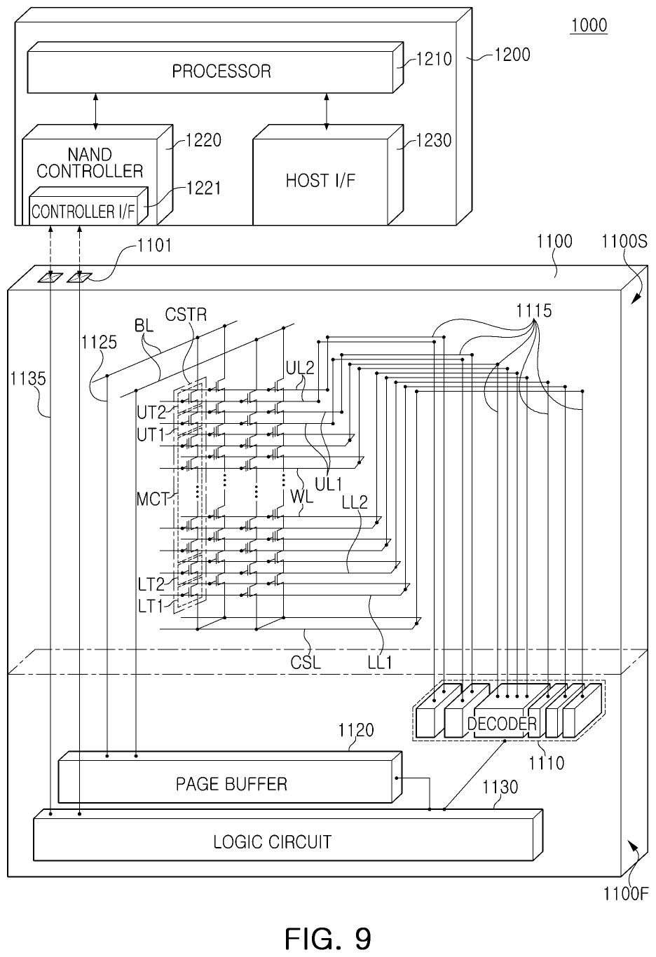

FIG. 9 is a view illustrating a data storage system including a semiconductor device according to an example embodiment.

Referring to FIG. 9, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 7. The semiconductor device 1100 may include a first structure 1100F and a second structure 1100S on the first structure 1100F. In the example embodiments, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the example embodiments.

In the example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In the example embodiments, the lower transistors LT1 and LT2 may include a lower erase control transistor LT1 and a ground select transistor LT2 connected (e.g., electrically connected) to each other in series. The upper transistors UT1 and UT2 may include a string select transistor UT1 and an upper erase control transistor UT2 connected (e.g., electrically connected) to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending between the first structure 1100F and the second structure 1100S. The bitlines BL may be electrically connected to the page buffer 1120 through second connection interconnections 1125 extending between the first structure 1100F and the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending between the first structure 1100F and the second structure 1100S.

The controller 1200 may include a processor 1210, a NAND controller 1220, and a host interface 1230. In the example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

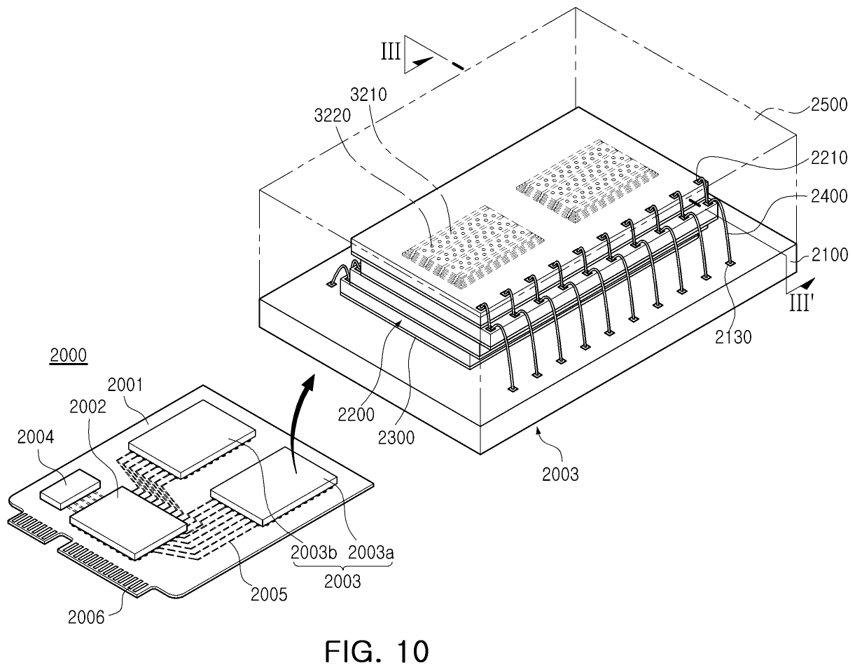

FIG. 10 is a perspective view illustrating a data storage system including a semiconductor device according to an example embodiment.

Referring to FIG. 10 a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected (e.g., electrically connected) to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 on (e.g., covering or overlapping) the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 9. Each of the semiconductor chips 2200 may include gate stack structures 3210 and channel structures 3220. Each of the semiconductor chips 2200 may include the semiconductor device described in the aforementioned example embodiment with reference to FIGS. 1 to 7.

In the example embodiments, the connection structure 2400 may be configured as a bonding wire electrically connecting the input/output pad 2210 to the package upper pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In the example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected (e.g., electrically connected) to each other by an interconnection formed on the interposer substrate.

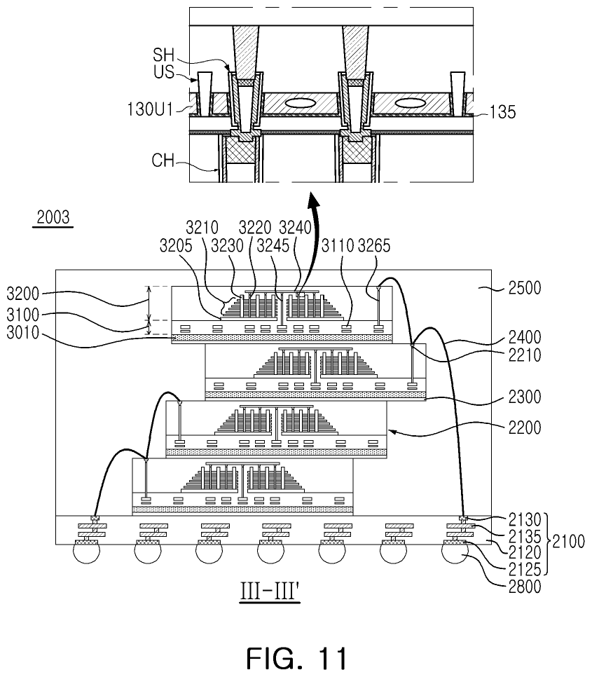

FIG. 11 is a cross-sectional view illustrating a semiconductor package according to an example embodiment, illustrating an example embodiment of the semiconductor package 2003 in FIG. 10 taken along line III-III′.

Referring to FIG. 11, in the semiconductor package 2003, the package substrate 2100 may be implemented as a printed circuit substrate. The package substrate 2100 may include a package substrate body portion 2120, package upper pads 2130 disposed on an upper surface of the package substrate body portion 2120, lower pads 2125 disposed on the lower surface of the package substrate body portion 2120 or exposed through the lower surface of the package substrate body portion 2120, and internal interconnections 2135 electrically connecting the package upper pads 2130 to the lower pads 2125 in the package substrate body portion 2120. The lower pads 2125 may be connected (e.g., electrically connected) to the interconnection patterns 2005 of the main board 2001 of the data storage system 2000 through the conductive connection portions 2800 as illustrated in FIG. 10.

Each of the semiconductor chips 2200 may include a semiconductor substrate 3010 and a first structure 3100 and a second structure 3200 stacked in order on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 extending in (e.g., penetrating through) the gate stack structure 3210, bitlines 3240 electrically connected to the channel structures 3220, and contact plugs 3235 electrically connected to the wordlines WL (see FIG. 9) of the gate stack structure 3210. As described above with reference to FIGS. 1 to 7, in each of the semiconductor chips 2200, the first upper gate electrodes 130U1 may include a metal material, and the gate barrier layers 135 may expose upper surfaces of the first upper gate electrodes 130U1 and may be on (e.g., cover or overlap) side surfaces and lower surfaces thereof.

Each of the semiconductor chips 2200 may include a through-interconnection 3245 electrically connected to the peripheral interconnections 3110 of the first structure 3100 and extending into the second structure 3200. The through-interconnection 3245 may be disposed on an external side of the gate stack structure 3210 and may further be disposed to extend in (e.g., penetrate through) the gate stack structure 3210. Each of the semiconductor chips 2200 may further include an input/output pad 2210 electrically connected to the peripheral interconnections 3110 of the first structure 3100.

According to the aforementioned example embodiments, by optimizing the material of the upper select gate electrode, the arrangement of the gate barrier layer, and the structure of the second channel structure extending in (e.g., penetrating through) the upper select gate electrode, and a semiconductor device having improved electrical properties and reliability and a data storage system including the same may be provided.

While the example embodiments have been illustrated and described above, it will be configured as will be apparent to those skilled in the art that modifications and variations could be made without departing from the scope of the present disclosure as defined by the appended claims.

What is claimed is:

1. A semiconductor device, comprising:
a first semiconductor structure that includes a substrate, circuit devices on the substrate, and circuit interconnection lines on the circuit devices; and
a second semiconductor structure on the first semiconductor structure,
wherein the second semiconductor structure includes:
a plate layer;
gate electrodes that include a lower select gate electrode, memory gate electrodes, and an upper select gate electrode sequentially stacked on the plate layer, wherein the gate electrodes are spaced apart from each other in a first direction that is perpendicular to an upper surface of the plate layer;
first isolation regions that extend in the lower select gate electrode and the memory gate electrodes in a second direction that is perpendicular to the first direction;
second isolation regions that extend in the upper select gate electrode in the second direction;
a horizontal insulating layer between the memory gate electrodes and the upper select gate electrode;
first channel structures that extend in the lower select gate electrode and the memory gate electrodes in the first direction;
second channel structures that extend in the upper select gate electrode and the horizontal insulating layer and are electrically connected to the first channel structures, respectively; and
a gate barrier layer on a side surface and a lower surface of the upper select gate electrode,
wherein the upper select gate electrode includes a metal material.

2. The semiconductor device of claim 1, wherein the gate barrier layer is in contact with side surfaces of the second isolation regions.

3. The semiconductor device of claim 1, wherein each of the second channel structures includes a second gate dielectric layer, a second channel layer, and a second channel buried insulating layer that are sequentially disposed on the upper select gate electrode, and
wherein the second channel layer has a pad portion that protrudes toward the horizontal insulating layer.

4. The semiconductor device of claim 3, wherein each of the second channel structures includes a second channel pad on the second channel buried insulating layer, and a pad oxide layer that overlaps at least a portion of an upper surface of the second channel pad and a portion of an upper surface of the second channel layer in the first direction.

5. The semiconductor device of claim 1, wherein the upper select gate electrode includes a void between the second channel structures and/or between the second channel structures and the second isolation regions.

6. The semiconductor device of claim 1, wherein a thickness of the upper select gate electrode is in a range of 600 Å to 900 Å.

7. The semiconductor device of claim 1, wherein side surfaces of the first isolation regions have regions that protrude toward the lower select gate electrode and the memory gate electrodes, and
wherein side surfaces of the second isolation regions extend at a constant slope toward the plate layer.

8. The semiconductor device of claim 1, wherein the first isolation regions and the second isolation regions are spaced apart from each other in a plan view, and
wherein the first isolation regions do not overlap the second isolation regions in the first direction.

9. The semiconductor device of claim 1, wherein an upper surface of each of the second isolation regions is at a same distance as an upper surface of each of the second channel structures from the plate layer in the first direction.

10. The semiconductor device of claim 1, wherein the upper select gate electrode, the lower select gate electrode, and the memory gate electrodes include a same material.

11. The semiconductor device of claim 1,
wherein a first shifted channel structure among the second channel structures is misaligned with respect to a first corresponding channel structure among the first channel structures by a first length in a third direction perpendicular to the first direction and the second direction, and
wherein a second shifted channel structure among the second channel structures is misaligned with respect to a second corresponding channel structure among the first channel structures by a second length that is different from the first length in the third direction.

12. The semiconductor device of claim 1, wherein the first channel structures have a first diameter, and the second channel structures have a second diameter smaller than the first diameter.

13. A semiconductor device, comprising:
a plate layer;
gate electrodes that are stacked and spaced apart from each other on the plate layer in a first direction that is perpendicular to an upper surface of the plate layer, wherein the gate electrodes include first gate electrodes and a second gate electrode on the first gate electrodes;
first channel structures that extend in the first gate electrodes in the first direction; and
second channel structures that extend in the second gate electrode in the first direction, wherein the second channel structures are electrically connected to the first channel structures, respectively,
wherein the second gate electrode includes a metal material, and
wherein each of the second channel structures includes a second channel layer, a second gate dielectric layer between the second channel layer and the second gate electrode, a second channel buried insulating layer on an internal side surface of the second channel layer, a second channel pad on the second channel buried insulating layer, and a second pad oxide layer on the second channel pad and the second channel layer.

14. The semiconductor device of claim 13, wherein the second gate dielectric layer is in contact with a side surface of the second pad oxide layer.

15. The semiconductor device of claim 13, further comprising:
a gate barrier layer on a side surface and a lower surface of the second gate electrode.

16. The semiconductor device of claim 13, wherein the second gate electrode has an inclined side surface, and
wherein a width of the second gate electrode increases toward the plate layer.

17. The semiconductor device of claim 13,
wherein each of the first channel structures includes a first channel layer, a first gate dielectric layer between the first channel layer and the first gate electrodes, a first channel buried insulating layer on an internal side surface of the first channel layer, and a first channel pad on the first channel buried insulating layer, and
wherein the second channel layer partially extends into the first channel pad and is electrically connected to the first channel pad.

18. The semiconductor device of claim 13, further comprising:
a stud on each of the second channel structures, wherein the stud extends into the second pad oxide layer and the second channel pad and is electrically connected to the second channel layer.

19. A data storage system, comprising:
a semiconductor storage device that includes a first semiconductor structure, a second semiconductor structure on the first semiconductor structure, and an input/output pad, wherein the first semiconductor structure includes circuit devices, and the input/output pad is electrically connected to the circuit devices; and
a controller that is electrically connected to the semiconductor storage device through the input/output pad and configured to control the semiconductor storage device,
wherein the second semiconductor structure includes:
a plate layer;
gate electrodes that are stacked and spaced apart from each other on the plate layer in a first direction that is perpendicular to an upper surface of the plate layer, wherein the gate electrodes include first gate electrodes and a second gate electrode on the first gate electrodes;
first channel structures that extend in the first gate electrodes in the first direction; and
second channel structures that extend in the second gate electrode in the first direction, wherein the second channel structures are electrically connected to the first channel structures, respectively,
wherein the second gate electrode includes a metal material, and
wherein each of the second channel structures includes a second channel layer, a second gate dielectric layer between the second channel layer and the second gate electrode, a second channel pad on an internal side surface of the second channel layer, and a second pad oxide layer on the second channel pad and the second channel layer.

20. The data storage system of claim 19, wherein the second gate electrode and the first gate electrodes include different materials.
